(19) United States
(12) Patent Application Publication
(10) Pub. No.: US 2011/0267759 A1
(43) Pub. Date: Nov. 3, 2011

(54) DISPLAY SCREEN MOUNT

(75) Inventors: Richard Anthony Abram, Perth (AU); Terence Mann, Sutton Coldfield (GB)

(73) Assignee: Tempus Computers Limited, Birmingham (GB)

(21) Appl. No.: 12/992,870

(22) PCT Filed: May 5, 2009
(86) PCT No.: PCT/EP2009/055405

§ 371 Date: Dec. 20, 2010

(30) Foreign Application Priority Data
May 15, 2008 (GB) 0808887.4

(51) Int. Cl. G06F 1/16; B23P 17/04; H05K 7/00

(52) U.S. Cl. 361/679.27; 361/679.01; 29/428

(57) ABSTRACT

A display screen mount for mounting a display screen to a vehicle dashboard having a generally planar portion, the generally planar portion having attachment features for receiving a display screen on a first side, the display screen mount further including at least one mounting arm projecting away from the generally planar portion on a second side of the generally planar portion.

The present invention relates to a display screen mount and method of mounting a display screen mount in a vehicle.

Vehicles, such as cars, are provided with various instruments such as speedometers, odometers, engine rev-counters, oil and water temperature gauges, oil pressure gauges, etc. This information allows the vehicle occupants, typically the driver, to monitor certain important aspects of the vehicle. The vehicle may also include entertainment sound systems such as an FM and/or AM radio receiver, a cassette tape player, a CD player or the like. Such systems are provided for the entertainment of vehicle occupants. Typically the entertainment sound system is provided in a central console of the vehicle and is readily accessible by both the driver and the front seat passenger.

The instruments and sound systems are provided by the vehicle manufacturer since they will be used by the majority of people using the vehicle.

However, certain specialist vehicle users, such as the police or other emergency services, will require specialist equipment to be used in the vehicle. Certain equipment, such as a video camera, requires a display screen to enable the vehicle occupants to monitor the image being recorded by the camera. Such a display screen must therefore be positioned within the vehicle so that it can be conveniently viewed by the vehicle occupants, typically the driver or the front seat passenger. The display screen may be incorporated as part of a laptop or so-called tablet PC having a reversible screen. In these circumstances, there may be a requirement for the laptop/tablet PC to make a data and/or power connection with a docking station whilst also being viewed by vehicle occupants. Thus, there is a requirement to conveniently and easily locate a display screen in the vehicle.

At the same time certain users may wish to continue to use entertainment sound systems and other vehicle facilities.

Thus, according to the present invention there is provided a display screen for mounting a display screen to a vehicle dashboard mount having a generally planar portion, the generally planar portion having attachment features for receiving a display screen on a first side, the display screen mount further including at least one mounting arm projecting away from the generally planar portion on a second side of the generally planar portion.

In one embodiment the display screen unit incorporates a hinge mechanism intermediate the generally planar portion and the mounting arm. Preferably a latch arrangement is provided to selectively retain the planar portion in a first position relative to the mounting arm.

According to another aspect of the present invention, there is provided a method of mounting a display screen mount having a generally planar portion, the generally planar portion having attachment features for receiving a display screen on a first side, the display screen mount further including at least one mounting arm projecting away from the generally planar portion on a second side of the generally planar portion in a vehicle including steps of providing a vehicle having a recess, inserting the at least one arm into the recess and securing the arm to the vehicle.

Advantageously, where the vehicle is provided with an entertainment sound system, this sound system can be removed from the vehicle and the arm or arms of the display screen mount can be inserted into the recess which previously contained the sound system and secured to the vehicle.

Because the entertainment sound system is typically provided on a central console, by securing the display screen mount to the recess provided for the entertainment sound system, a display screen mounted on the display screen mount will then be readily viewable by the driver and the front seat passenger.

In a further advantageous arrangement, a mechanism intermediate the generally planar portion and the mounting arm may be provided so that a user can access vehicle controls behind the planar portion.

The invention will now be described by way of example only, with reference to the accompanying drawings in which:

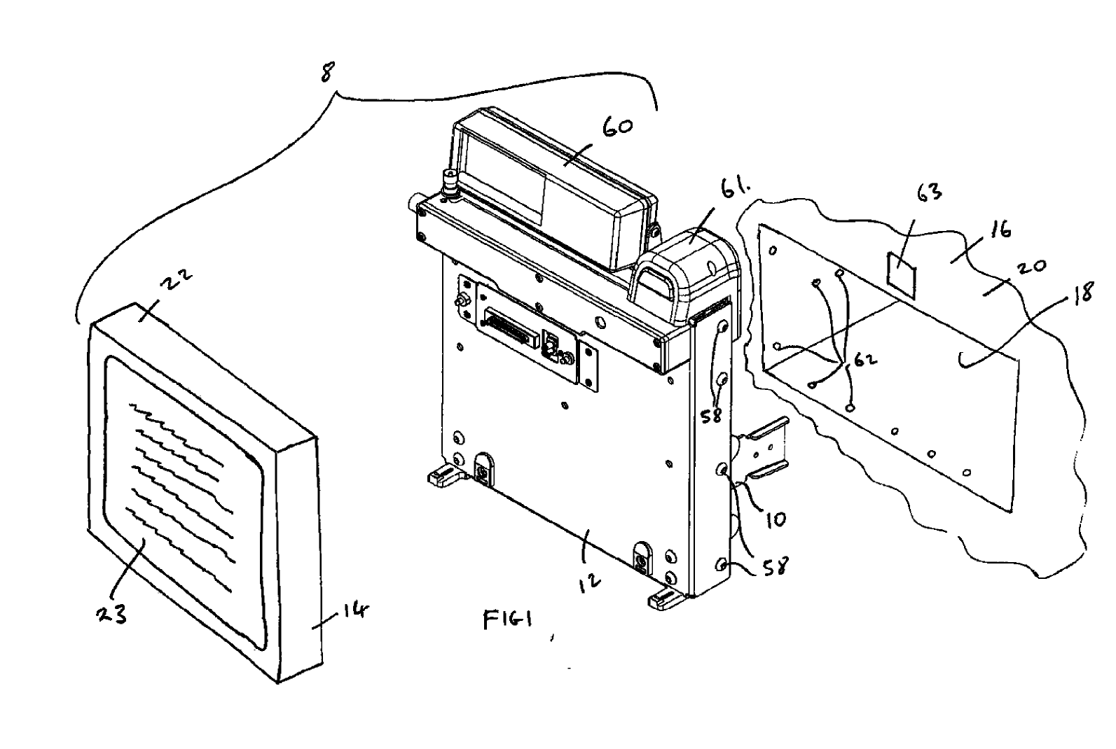

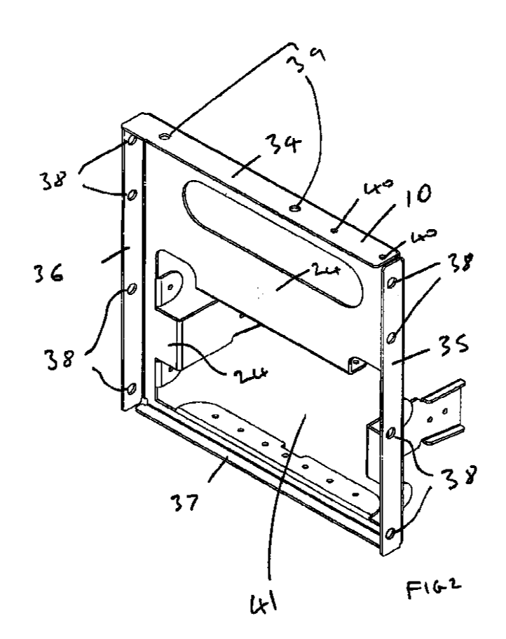

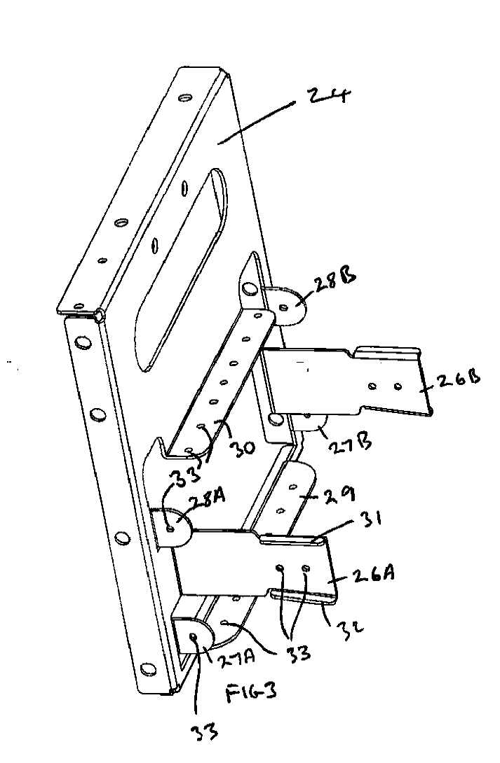

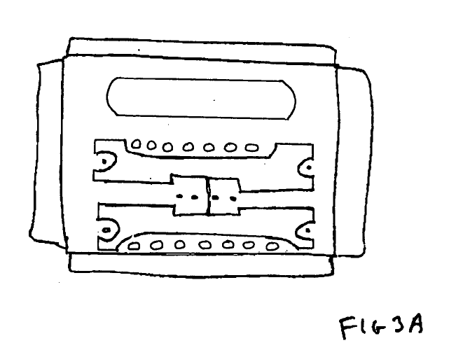

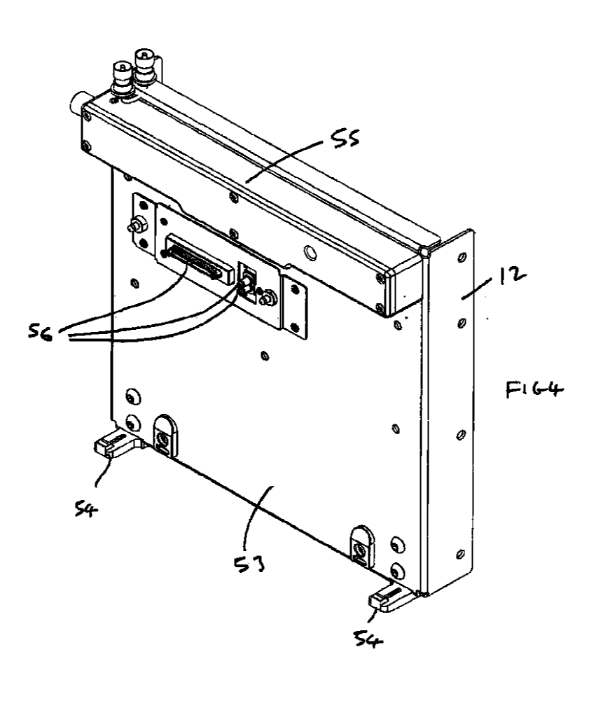

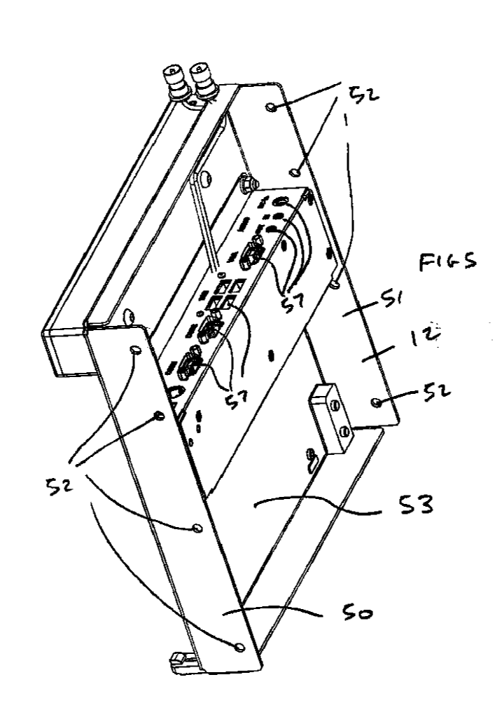

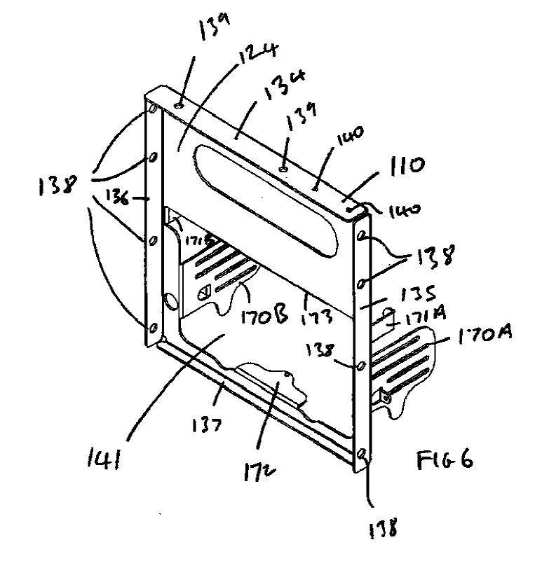

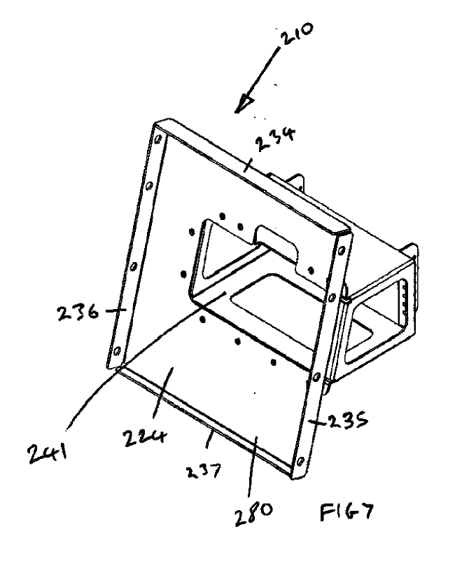

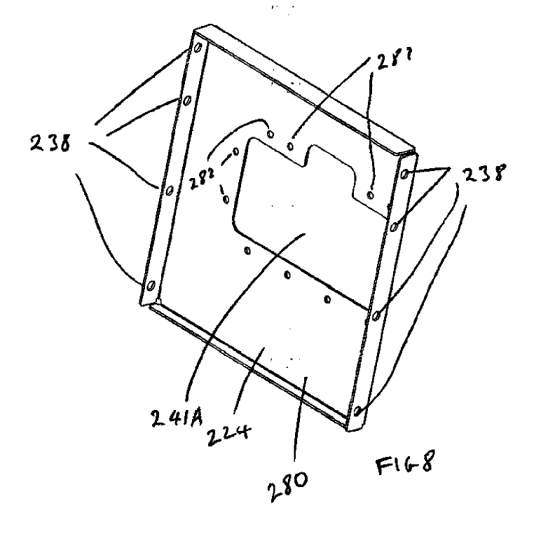

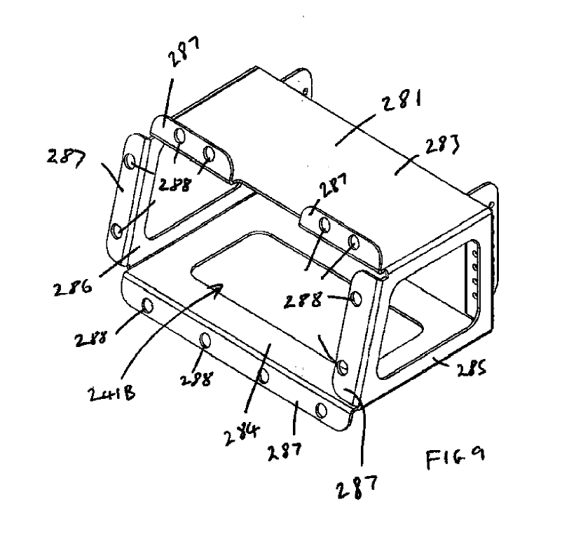

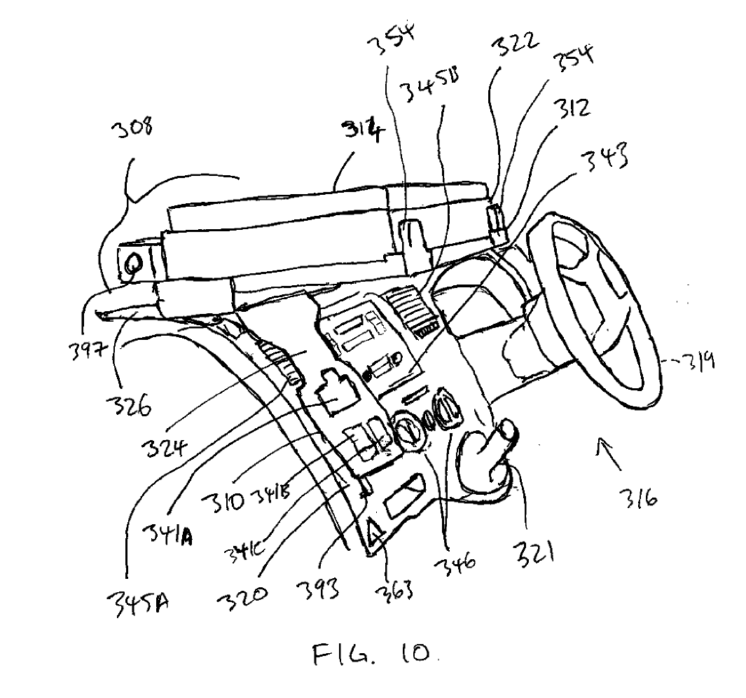

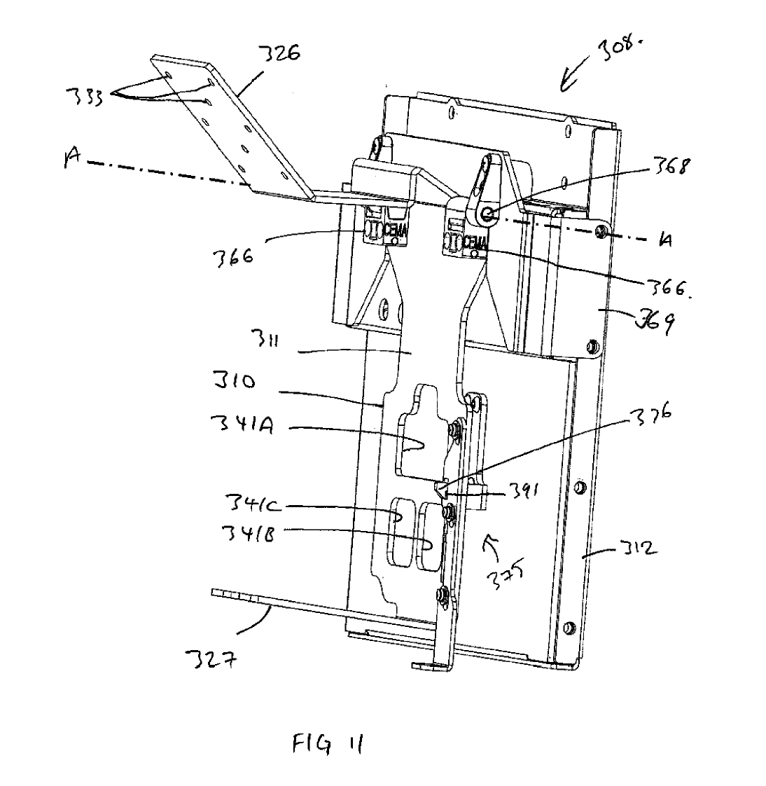

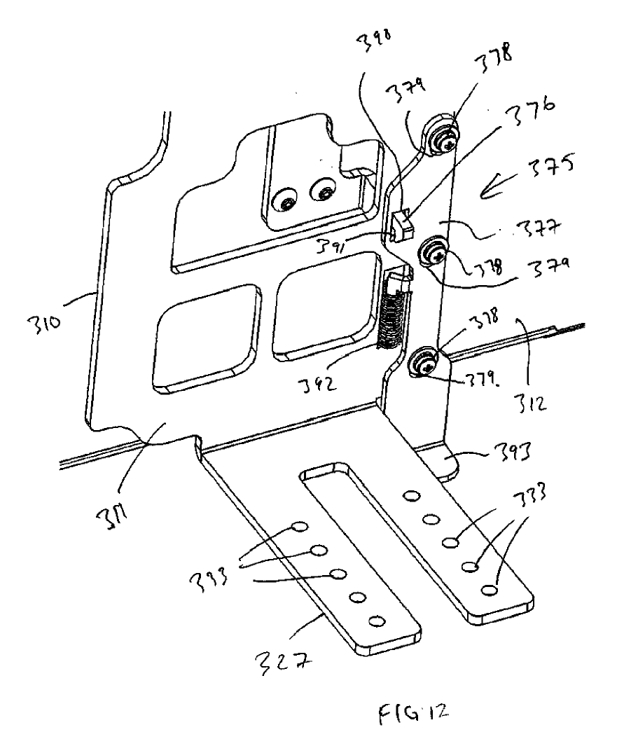

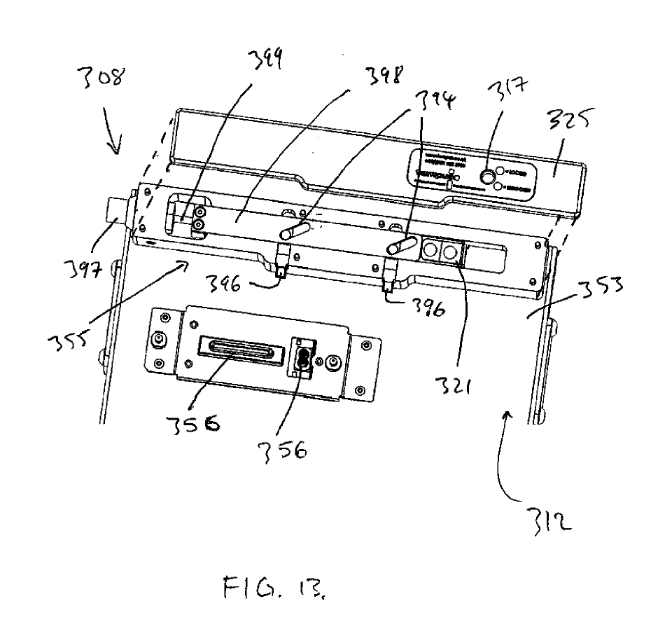

FIG. 1 is an exploded isometric view of a display screen mount according to the present invention, a display screen docking station, a display screen and a vehicle recess to which the display screen mount is attached;

FIGS. 2 and 3 are isometric views of the display screen mount of FIG. 1;

FIG. 3A is a developed view of the display screen mount of FIG. 1;

FIGS. 4 and 5 are isometric views of the display screen docking station of FIG. 1;

FIG. 6 is an isometric view of a second embodiment of a display screen mount according to the present invention;

FIG. 7 is an isometric view of a third embodiment of a display screen mount according to the present invention;

FIGS. 8 and 9 show isometric views of the two major components of the display screen mount of FIG. 7;

FIG. 10 is a perspective view of a display screen assembly incorporating a display screen mount according to a fourth embodiment of the present invention when fitted to a vehicle dashboard;

FIG. 11 is a rear perspective view of the display screen mount of FIG. 10;

FIG. 12 is an enlarged view of the latching assembly of the display screen mount of FIG. 10;

FIG. 13 is a partially exploded perspective view of the docking station portion of the display screen assembly and FIG. 10; and

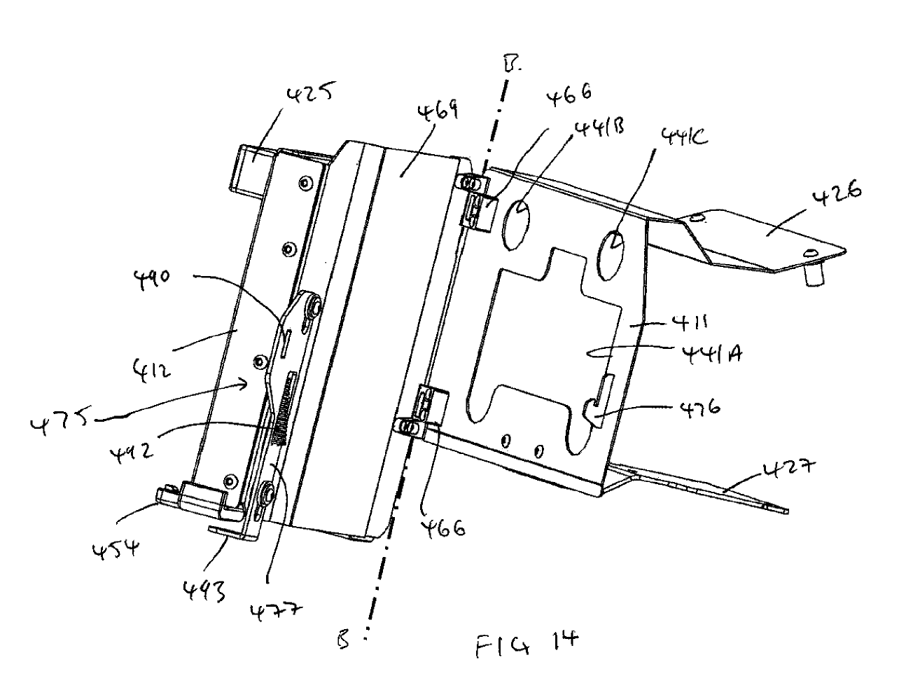

FIG. 14 is a perspective view of a display screen incorporating a display screen mount according to a fifth embodiment of the present invention.

With reference to FIGS. 1 to 5, there is shown a display screen mount 10, a display screen docking station 12, a display screen 14 and a vehicle 16 (only part of which is shown) having a recess 18.

A central console 20 of the vehicle 16 includes recess 18. Recess 18 is sized to receive an entertainment sound system. DIN standard 75490 and international standard ISO 7736 provide a standard set of sizes for entertainment sound systems for vehicles. This allows after-market sound system manufacturers to design their systems to be compatible with the standardised recesses that the manufacturers provide in their vehicles. The “single” DIN size is 180 mm wide by 50 mm tall. The “double” DIN is 180 mm wide by 100 mm tall. In this case, the recess 18 is made to “double” DIN.

The display screen 14 (shown schematically) can be any type of display screen, but will typically be a LCD (liquid crystal display) display screen. In this case the display screen 14 forms part of a “laptop” computer 22. In this case the computer 22 is a “Toughbook CF-19” manufactured by Panasonic. The computer 22 has a computer screen 23.

In summary, a display screen mount 10 is secured in the recess 18. The display screen docking station 12 is then secured to the display screen mount 10. The laptop computer 22 can then be docked with, and undocked from, the display screen docking station 12. When the laptop computer 22 is docked with the display screen docking station it is in a position that is readily viewable by the vehicle driver and other vehicle occupants.

In more detail, the display screen mount 10 is made from a sheet material, in this case a sheet of aluminium alloy. The display screen mount has a generally planar portion 24 from which various tabs and arms are folded either forwards (i.e. towards the display screen docking station) or backwards (i.e. away from the display screen docking station). As best seen in FIG. 3, arms 26A, 26B, 27A, 27B, 28A, 28B, 29 and 30 are all bent backwards and are at approximately 90° to the generally planar portion 24.

Arm 26A includes tabs 31 and 32 bent at 90° at arm 26A. Arm 26B has similar tabs to arm 26A. Each of the arms includes one or more hole 33.

The display screen mount 10 also includes arms 34, 35, 36 and 37 all of which are bent forwards at approximately 90° to the generally planar portion 24. Arms 35 and 36 are symmetrical about a vertical centre line of the display screen mount 10 and include holes 38.

Arm 34 includes holes 39 and 40.

FIG. 3A shows the developed view of the display screen mount 10 prior to the arms being folded into the position shown in FIGS. 2 and 3. A comparison between FIG. 3A and 2 shows that once the arm 26A, 26B, 27A, 27B, 28A, 28B, 29 and 30 are folded into their FIG. 2 position, the act of folding these arms creates a relatively large access hole 41 the purpose of which will be further described below. Note that arms 170A, 170B, 171A, 171B, 172 and 173 can all be bent from a single piece of sheet material, since, in the developed shaped none of the arms overlap each other.

The display screen docking station 12 (which in this case is a computer laptop docking station, since it is designed to fit the laptop computer 22), includes side panels 50 and 51 each of which includes holes 52 which, when assembled onto the display screen mount 10 align with corresponding holes 38. The display screen docking station includes a generally planar panel 53 which lies parallel to the generally planar portion 24. The display screen docking station includes two projections 54 positioned at the bottom of the docking station and a locking mechanism 55 positioned at the top of the docking station. The docking station 12 includes electrical connectors 56 which connect to further electrical connectors (not shown) on the back of the laptop computer 22.

At the back of the docking station there are electrical connectors 57 (connected to appropriate connectors 56) which allow the docking station to be connected to ancillary equipment, such as a video camera, sound recording equipment, a calibrated speedometer, a calibrated odometer, a power supply and the like.

Mounted on the top of the display screen mount 10 via holes 39 is a two-way radio 60 to enable police officers and the like to communicate with their police station. Mounted on the top of the display screen 10 via holes 40 is a hazard warning switch 61.

### Installation and Operation of the System is as Follows:

By way of example, it is assumed that vehicle 16 is a car supplied from the vehicle manufacturer to a police force. It is also assumed that the car is supplied with a combined radio/CD player sound system which is installed in recess 18.

The combined radio/CD player sound system is first removed from the recess 18. The arms 26A, 26B, 27A, 27B, 28A and 29B are inserted into the recess 18. Once the display screen mount is correctly positioned within recess 18, certain holes 33 of the display screen mount 10 will align with certain holes 62 of the recess 18. Fixings, typically self-tapping screws can then be used to secure the display screen mount 10 to the vehicle via one or more holes 33 and 62. Note that where self-tapping screws are used, the access hole 41 is sufficiently large for the fitter to pass the screw and associated screwdriver and his or her hand through the access hole 41 to enable the screws to be tightened.

In further embodiments, captive fasteners may be used, i.e. fasteners which are held captive in one or more holes 33 of the display screen mount prior to insertion of the arms into the recess 18. Under such circumstances, the access hole 41 allows access for a screwdriver, or the like, and the hand of the fitter to tighten the screws. In further embodiments the captive fasteners may not require any tool for tightening and the like. Under such circumstances, the access hole 41 allows the fitter to pass his hand through the access hole 41 and tighten the fixings. Note that by providing a display screen mount made from sheet material having one or more arms bent backwards from a generally planar portion 24, the act of bending the arms backwards automatically provides the access hole 41 which can subsequently be used to secure the arms to the vehicle.

The two-way radio 60 can then be mounted on the top of the display screen mount assembly as can the hazard warning switch 61.

As shown in FIG. 1, the vehicle was originally provided with a hazard warning switch 63. It will be appreciated that once the display screen assembly 8 is in position, the original hazard warning switch 63 is obscured and cannot be used. Thus electrical leads which connect to the original hazard warning switch 63 can be extended and connected to the hazard warning switch 61. Accordingly, the original hazard warning switch 63 then becomes redundant and, should it be required to turn the hazard warning lights on, this can be achieved by using the hazard warning switch 61.

Once the display screen mount 10 is mounted on the vehicle, the various electrical wires for connecting to electrical connectors 57 can be provided and then the appropriate connections can be made when the docking station is near the display screen mount. Once all electrical connections are made, the display screen docking station can be positioned relative to the display screen mount such that holes 52 align with corresponding holes 38. Holes 38 include captive nuts (not shown) and, accordingly, screws 58 can be passed through holes 52, holes 38 and tightened into the corresponding captive nut. In this case, the screws 58 are of a “security” type screw, i.e. the tightening feature is shaped to only receive a special tightening tool. Examples of security screws are tamper-resistant TORX (often referred to as TORX TR) and Tamper-Resistant TORX-Plus, (which has five lobes and a central post). Screws 58 cannot be tightened (and more particularly, cannot be loosened) by standard tools such as screwdrivers, spanners, adjustable spanners or alien keys.

Once the display screen docking station 12 is in place, then the laptop computer 22 can be docked with the docking station. In this case, a lower part of the laptop computer 22 is positioned on the projections 54 and the top part of the computer 22 is then swung into position beneath the locking mechanism 55. The laptop computer can then be locked to the docking station using the locking mechanism 55. Locking mechanisms for docking stations are known and, as such, the locking mechanism 55 will not be described in further detail. In order to release the laptop computer 22, a key or other coded security device is required to release the locking mechanism whereupon the computer can be undocked from the docking station.

It will be appreciated that once the laptop computer is docked with the docking station and the locking mechanism has been secured, then it is not possible for an unauthorised user, such as a thief, to steal the laptop computer alone. Because the screws 58 are security screws, it is not possible for a thief to remove the docking station from the display screen mount without having the specialist tool to remove screws 58. Significantly, the generally planar panel 53 covers the access hole 41 thus it is not possible to gain access to the screws or other fixing devices that secure the display screen mount 10 to the vehicle 16.

With reference to FIG. 6, there is shown a second embodiment of a display screen mount 110 with components which fulfil the same function as those in display screen mount 10 labelled 100 greater. Display screen mount 110 is designed for use on a different vehicle than vehicle 16.

In this case arms 170A, 170B, 171A, 171B, 172 and 173 differ in shape from the equivalent arms on the display screen mount 10 simply because display screen 110 is designed to be fitted on a different vehicle to vehicle 16. In this case, arms 134, 135, 136 and 137 are identical to corresponding arms 34, 35, 36 and 37. As such, it will be appreciated that the two-way radio 60, hazard warning switch 61, display screen docking station 12 and laptop computer 22 can all be fitted to the display screen mount 110.

With reference to FIGS. 7 to 9, there is shown a third embodiment of a display screen mount 210 with components which perform a similar function to those of display screen mount 10 labelled 200 greater. Display screen mount 210 is designed for use on a different vehicle than vehicle 16 and the vehicle for which display screen mount 110 is designed.

In this case, display screen mount 210 is formed from two major components, namely a front panel 280 and a mounting arm 281. The front panel includes a generally planar portion 224 having an access hole 241A. Around the periphery of the access hole 241A there are a series of holes 282. The mounting arm 281 is cube-like having a top panel 283, a bottom panel 284, a right side panel 285 and a left side panel 286. Tabs 87 are bent from appropriate top, bottom, right side and left side panels and include holes 288 which correspond with holes 282. The top panel, bottom panel, right side panel and left side panel together form access hole 241B. Nuts (not shown) and bolts (not shown) secure the front panel 280 to the mounting arm 281. Access holes 241A and 241B are aligned and thus together form access hole 241.

Thus, once the front panel 280 has been secured to the mounting arm 281, as shown in FIG. 7, then this subassembly can be assembled into the vehicle. The display screen docking station 12 can then be attached to the display screen mount 210 as previously discussed. In this case, no provision is made for mounting a two-way radio, since this radio is positioned elsewhere within the associated vehicle. Also, no provision is made for mounting a hazard warning switch since the hazard warning switch is not obscured by the display screen assembly in the associated vehicle.

FIGS. 10 to 13 illustrate a fourth embodiment of the present invention that differs from the preceding three embodiments in that it is provided with a different mounting arrangement onto the vehicle dashboard, and by the fact that a hinge and latching mechanism is included, as is discussed in more detail below.

Like parts have been illustrated, where possible, by like numerals but with the addition of the prefix “3”. Only those parts that differ from the preceding embodiments are discussed in more detail below.

With reference to FIG. 10, the dashboard of a vehicle 316 including a central console 320 is shown. The vehicle is a van and therefore the central console is somewhat wider than for the passenger cars of the preceding embodiments and also incorporates gearstick 321 adjacent the driver's seat (not shown) and steering wheel 319 at the right hand side of the console 320, since this vehicle is right hand drive.

It can be seen that the central console includes an entertainment sound system 343, a first air vent 345A, and a second air vent 345B, ventilation control 346 and a hazard warning switch 363.

The display screen mount 310 of this embodiment is fitted to the left hand side of the central console 320 and is shown in FIG. 10 with the display screen 314 and display screen docking station 312 in a lifted position. On left-hand drive vehicles, the display screen mount 310 may be mounted at the right-hand side of the console.

It can be seen that the entertainment sound system 343, ventilation controls 346, second air vent 345B, hazard warning switch 363, as well as additional vehicle controls (not visible) behind access holes 341A, 341B and 341C, are accessible when in this position. In fact, the only feature of the central console to be partially obscured is the left hand air vent 345A. Therefore, unlike the display screen mounts of the preceding embodiments, it is possible for the occupants of the vehicle to continue to have access to all vehicle functions, including the entertainment sound system, with the one potential exception being some impairment of the ventilation air flow.

FIGS. 11 and 12 show the mounting arrangement of the display screen mount 310 of this embodiment of the present invention. The display screen mount 310 comprises a generally planar body portion 324 which terminates at its upper end in a first arm 326, and at its lower end in a second arm 327. The first arm 326 and the second arm 327 are formed from the same blank metal sheet (e.g. of aluminium alloy as in the preceding embodiments) that is bent to form the arms at angles appropriate to the vehicle onto which it is to be installed.

In this embodiment, the first arm 326 is angled so as to contact a surface (e.g. a coin tray) on the top of a vehicle dashboard, and is provided with a number of holes 333 through which, for example, self tapping (and tamper resistant) screws can be inserted to secure the arm to the dashboard.

With reference to FIG. 12, it can be seen that the second arm 327 is forked along the majority of its length and also provided with rows of holes 333 along each fork. This arrangement enables the second arm 327 to be inserted into two adjacent apertures in the dashboard that are normally covered by blanking plates and available in normal circumstances for the provision of additional switchgear if it is needed. Again, suitable self tapping screws may be used to secure the arm 327 to the internal walls of this aperture. As in the previous embodiments, the screws may be provided with tamper resistant type heads in order to reduce the risk of theft of the docking station 312.

The spaced, two point fixing provides a secure mount that has been found to pass standard frontal and side impact tests.

A pair of hinges 366 is mounted at the upper edge of the display screen mount body such that the hinge shafts 368 are coaxially aligned about a substantially horizontal axis A-A. In other embodiments, the hinges could be mounted such that the axis of the shaft 368 is vertical, or inclined to the vertical with the hinges being mounted to one side of the display screen mount body. Alternatively, the hinges 366 may be mounted to the bottom of the display screen mount planar portion 324 with the axis A-A also being substantially horizontal, so the display screen docking station 312 can pivot forward and down from the bottom.

The hinges 366 pivotally mount a generally planar portion 353 of the display screen docking station 312 to the display screen mount 310 via a bracket 369 that is also formed from a blank in the form of a sheet of metal that is bent to the required shape and attached to the sides of the display screen docking station 312. Thus, when installed on a vehicle as illustrated in FIG. 10, the display screen docking station 312 is able to pivot upwards about axis A-A with respect to the display screen mount 310 from the position shown in FIG. 11 to the raised position shown in FIG. 10.

The hinges 366 have sufficient internal friction to hold the docking station 312 in a lifted position and preferably are of the kind having an asymmetric torque value so are easier to lift. Such hinges are available, e.g. from Southco of Worcester, United Kingdom. Alternatively, a biasing device such as a spring or gas strut may bias the docking station into the uppermost position in certain embodiments.

Since the display screen assembly 308 is intended to be mounted on a vehicle subject to movement, it is important that unwanted movement of parts of the assembly 308 is prevented as the vehicle travels over bumps in the road. To this end, a spring loaded latch arrangement 375 is provided to control the hinging motion. An arrow-headed staple 376 is secured to the rear face of the display screen docking station 312 so as to project perpendicularly away from this surface. A latch bolt 377 in the form of an elongate plate is mounted to slide parallel to the plane of the display screen mount body 353 by virtue of an arrangement of screws 378 secured through slotted holes 379 on the latch bolt 377. A further hole 390 is provided on the latch bolt 377 to receive the head of staple 376 and retain the staple 376 by virtue of contact between the surrounding surface of the latch bolt, and an abutment surface 391 of the staple 376. The latch bolt 377 is biased into an upward, latched condition by a helical spring 392 that is grounded on the display screen mount body 353. However, in FIGS. 11 and 12 the latch bolt 377 is shown in its lowermost, unlatched condition.

A lowermost portion of the latch bolt 377 projects below the display screen docking station and is bent through substantially 90 degrees to form a release handle 393. It will be appreciated that the ramped surface of the staple 376 enables the display screen docking station to be brought into a latched condition without any interaction by the user of the assembly, and to be easily released by pulling on the release handle 393.

FIG. 13 is a partially exploded view of the front face of the docking station 312 against which a display screen or laptop computer 314 is secured.

As can be seen from FIG. 10, in this embodiment the front edge of the laptop 314 is retained by projections 354, whereas, as can be seen in FIG. 13 the rear edge is engaged by teeth 396 of a locking mechanism 355 that extend into corresponding recesses (not shown) on the rear edge of the laptop 314. The position of teeth 396 is controlled by a key operated lock 397, which in turn shifts a control bar 398 to the deployed position shown in FIG. 13 from its spring biased rest position further to the left than is shown in FIG. 13. This is achieved by linear motion of a lock output member 399 in conjunction with angled slots 394 in the control bar 398 that act on followers of the teeth 396 and the spring biasing.

It is important that users of the display screen docking station 312 can be confident that docking has properly been achieved, both mechanically between the teeth 396 and the laptop, and electrically from the electrical connectors 356.

To this end, a coloured visual indicator 321 comprising a green colour to indicate a locked and a red colour to indicate an unlocked state is connected for linear motion with the control member 398. An aperture 317 is provided at an appropriate location on a cover portion of 325 of the mechanism so that an appropriate colour is visible dependent upon the position of the control member 398. In a particularly preferred embodiment, a backlight (e.g. an LED) is provided to ensure that the locking indication is provided even if the vehicle is dark. The teeth 396 configured such that an electrical connection can only be made if a proper mechanical connection is made with the teeth. Therefore, the visual indication provides confirmation both of a mechanical securement of the display screen/laptop 314 in the docking station 312, and also a proper electrical and data connection too.

FIG. 14, an isometric view of a display screen assembly 408 incorporating a display screen mount 410 of a further embodiment of the present invention. Like parts have been illustrated, where possible, by like numerals but with the addition of the prefix “4”. Only those parts that differ from the preceding embodiments are discussed in detail below.

The assembly of FIG. 14 bears closest similarity to that of the fourth embodiment in that arms 426 an 427 mount the mount body 411 to the top of a dashboard, and into a dashboard recess respectively, in that the mount body 411 has access holes 441A, 441B and 441C to access vehicle controls, and in that the docking station 412 is hinged to the mount body 411 via a bracket 469 and also comprises a latch mechanism 475. However, the display screen mount of FIG. 14 also includes a number of substantial differences over the other embodiments. The mount body 411 is located centrally with respect to the dashboard centre console of the vehicle (not visible) which, in this embodiment, is a pick-up truck. Consequently, the large access hole 441A provides access to a vehicle entertainment sound system, but the ventilation controls are positioned below the lowermost edge of the mount body 411 and therefore do not require access holes. In addition, in this embodiment the docking station 412 is arranged to hinge about a left-hand edge of the mount body, with the hinge axis B-B being generally vertical, but inclined, to an extent from the vertical. This arrangement enables a driver of a right-hand drive vehicle to have the best access to the controls on the centre console. For left-hand drive vehicles, the position of the hinge may be reversed.

Finally, in this embodiment, the latch mechanism 475 is positioned with the latch bolt 477 slidable with respect to the bracket 469, rather than the mount body 411. The mechanism 475 is further arranged such that the release handle is pushed upwardly to release, rather than pulled downwardly, as in the fourth embodiment.

Whilst the embodiments described above are used to mount the display screen of a laptop computer, in further embodiments the display screen mount could be used to mount any type of display screen, in particular display screens which do not form part of a computer or are directly coupled to a computer. The physical and/or electrical docking formations may be adjusted as appropriate for mounting such alternative devices.

Whilst the embodiments are described above, a docking station has been secured to the display screen mount and a display screen can be docked and undocked with the docking station. In further embodiments, a docking station is not required. Thus, a display screen can be mounted directly on the display screen mount.

In the embodiments described above, the recess 18 originally housed an entertainment sound system. In further embodiments, any recess of the vehicle could be used. In particular, where vehicles are fitted with clocks, the clock can be removed and a display screen mount can be secured using the clock recess. In further embodiments, where the vehicle is provided with a fresh air vent or an air conditioning vent the vent can be removed and the display screen mount can be provided in the vent recess.

Instead of a hinge mechanism, an alternative arrangement may be provided, such as a slide mechanism or a “parallelogram” linkage-type hinge that allows the planar portion to translate relative to the mounting arm.

Various alternative forms of latch mechanism may be provided in place of that described, and the orientations and positions thereof may be altered.

It will be appreciated that in the embodiments described above, the mounting arm projects generally perpendicularly from the generally planar portion, although this will vary dependent upon the shapes of vehicle dashboards and location of recesses or other points of attachment.

What is claimed:

1. A display screen mount for mounting a display screen to a vehicle dashboard having a generally planar portion, the generally planar portion having attachment features for receiving a display screen on a first side, the display screen mount further including at least one mounting arm projecting away from the generally planar portion on a second side of the generally planar portion.

2. A display screen mount according to claim 1, further comprising a mechanism to enable the planar portion to move relative to the mounting arm.

3. A display screen mount according to claim 2 wherein the mechanism is a hinge mechanism.

4. A display screen mount according to claim 3, wherein the hinge axis is substantially horizontally arranged in use.

5. A display screen mount according to claim 2, wherein there is further provided a latch arrangement to selectively retain the planar portion in a first position relative to the mounting arm.

6. A display screen mount according to claim 1, including two mounting arms.

7. A display screen mount according to claim 2 wherein a second generally planar portion connects the two mounting arms.

8. A display screen mount according to claim 1 wherein at least one arm is configured to be secured to a dashboard recess.

9. A display screen mount according to claim 8, in which at least one arm is configured to be secured in a single DIN or double DIN recess.

10. A display screen mount according to claim 7, in which at least one of the first and second generally planar portions includes an access hole proximate the at least one arm to allow access to secure the at least one arm to an associated vehicle.

11. A display screen mount according to claim 7, wherein the second generally planar portion includes an access hole to access a vehicle facility.

12. A display screen mount according to claim 1, in which the mount is made from sheet metal.

13. A display screen mount according to claim 12 wherein at least one arm is bent from at least one of the first and second generally planar portions.

14. A display screen mount according to claim 13 wherein at least one arm is bent from a part of the generally planar portion of a blank that forms an access hole.

15. A display screen mount according to claim 1, further comprising a display screen docking station secured to the generally planar portion via the attachment features.

16. A display screen mount according to claim 15, in which at least one of the first and second generally planar portions includes an access hole proximate the at least one arm to allow access to secure the at least one arm to an associated vehicle and in which the display screen docking station includes a generally planar panel which covers the access hole.

17. A display screen mount according to claim 15 further comprising a display screen mounted in the display screen docking station.

18. A display screen mount according to claim 17, in which at least one of the first and second generally planar portions includes an access hole proximate the at least one arm to allow access to secure the at least one arm to an associated vehicle and in which display screen covers the access hole.

19. A display screen mount according to claim 17 in which the display screen is provided on a laptop computer and the display screen docking station is a laptop computer docking station.

20. A method of mounting a display screen mount in a vehicle including steps of:
providing a vehicle having a recess;
providing a display screen mount having a generally planar portion, the generally planar portion having attachment features for receiving a display screen on a first side, the display screen mount further including at least one mounting arm projecting away from the generally planar portion on a second side of the generally planar portion;
inserting the at least one mounting arm into the recess; and
securing the at least one mounting arm to the vehicle.

21. A method of mounting a display screen as defined in claim 20, including the step of removing one or more components of the vehicle from the recess to allow the arm to be inserted into the recess.

22. A method of mounting a display screen as defined in claim 20 including the step of using fasteners to secure the display screen mount to the vehicle and utilising an access hole to access the fasteners when securing the display screen mount to the vehicle.

23. A display screen mount for mounting a display screen over a vehicle dashboard, the display screen mount including:
a mounting portion for mounting the display screen to the display screen mount;
a mounting arm for securing the display screen mount over the dashboard;
a hinge mechanism between the mounting arm and the mounting portion;
a latch mechanism to releasably retain the mounting portion in a first position over the dashboard, wherein upon release of the latch mechanism the mounting portion may be pivoted to a second position at which an area of the dashboard that was previously inaccessible may now be accessed.

24. A display screen mount according to claim 23 wherein the mounting portion comprises a docking station to which the display screen may be selectively docked and undocked and which is configured to supply an electrical connection to the display screen when the display screen is docked therewith.
